(19) United States
(12) Patent Application Publication
(10) Pub. No.: US 2023/0211957 A1
(43) Pub. Date: Jul. 6, 2023

(54) ARTICLE TRANSFERRING APPARATUS, METHOD OF MEASURING STEP DIFFERENCE OF TRAVEL RAIL, AND TRANSFERRING SYSTEM

(71) Applicant: SEMES CO., LTD, Cheonan-si (KR)

(72) Inventor: Hyo Joo JEOUN, Hwaseong-si (KR)

(73) Assignee: SEMES CO., LTD, Cheonan-si (KR)

(21) Appl. No.: 18/148,152

(22) Filed: Dec. 29, 2022

(30) Foreign Application Priority Data
Dec. 31, 2021 (KR) 10-2021-0194296

(51) Int. Cl. B65G 17/12

(52) U.S. Cl. CPC B65G 17/12

(57) ABSTRACT

Disclosed is an article transferring apparatus, including: a vehicle traveling along a travel rail installed on a ceiling; a hoist module connected to the vehicle and transferring an article; a step difference measurement unit which is installed in the vehicle, and measures a step difference of the travel rail by measuring distances values to a traveling surface of the travel rail by a first displacement sensor and a second displacement sensor arranged at a predetermined interval along a travel direction; and a controller for determining whether there is a step difference of the travel rail by correcting an error between a first measurement value of the first displacement sensor and a second measurement value of the second displacement sensor according to an inclination of the vehicle.

### CROSS-REFERENCE TO RELATED APPLICATIONS

This application claims priority to and the benefit of Korean Patent Application No. 10-2021-0194296 filed in the Korean Intellectual Property Office on Dec. 31, 2021, the entire contents of which are incorporated herein by reference.

### TECHNICAL FIELD

The present invention relates to an article transferring apparatus.

### BACKGROUND ART

In general, in order to manufacture a semiconductor device, various types of processes, such as deposition, photography, and etching, are performed, and devices performing each of these processes are arranged in a semiconductor manufacturing line. Objects, such as wafers, for performing a semiconductor device manufacturing process may be provided to each semiconductor processing device in a state accommodated in a container, such as a FOUP. In addition, objects which has been processed may be recovered from each semiconductor processing device into a container, and the container including the recovered object may be transferred to the outside.

The container is transferred by the Overhead Hoist Transport (OHT) device. The OHT device transfers a container containing an object to a load port of any one of semiconductor processing devices. In addition, the OHT device may pick up a container containing a processed object from a load port and transfer the container to the outside or to another one of semiconductor processing devices.

The OHT device moves along the travel rail, and if there is a step difference of more than a certain level in the assembly part of the travel rail, the vibration applied to the OHT and the container increases, to affect to some modules, such as wheels, as damage.

In the past, two displacement sensors were used to detect a step difference of the travel rail to determine whether there was abnormality, and there is a problem in that in the section where the OHT accelerates and decelerates, the OHT is inclined under the influence of micro-levitation, and the inclination of the OHT causes to deterioration of accuracy of detection values of the displacement sensors.

### SUMMARY OF THE INVENTION

The present invention has been made in an effort to provide an article transferring apparatus capable of accurately measuring a step difference of a travel rail even in acceleration and deceleration sections, a method of measuring a step difference of a travel rail, and a transferring system.

The object of the present invention is not limited thereto, and other objects not mentioned will be clearly understood by those of ordinary skill in the art from the following description.

An exemplary embodiment of the present invention provides an article transferring apparatus, including: a vehicle traveling along a travel rail installed on a ceiling; a hoist module connected to the vehicle and transferring an article; a step difference measurement unit which is installed in the vehicle, and measures a step difference of the travel rail by measuring distances values to a traveling surface of the travel rail by a first displacement sensor and a second displacement sensor arranged at a predetermined interval along a travel direction; and a controller for determining whether there is a step difference of the travel rail by correcting an error between a first measurement value of the first displacement sensor and a second measurement value of the second displacement sensor according to an inclination of the vehicle.

Further, the article transferring apparatus may further include an inclination sensor unit for detecting an inclination angle of the vehicle and providing the inclination angle value to the controller.

Further, the controller may correct an error between the first measurement value and the second measurement value by using the inclination angle, and calculates a first distance value at which the first displacement sensor is orthogonal to the traveling surface and a second distance value at which the second displacement sensor is orthogonal to the traveling surface.

Further, the controller may calculate an error value by multiplying a sine value (sin θ) of the inclination angle by a distance value between the first displacement sensor and the second displacement sensor, and calculate an actual distance value at which the front displacement sensor is orthogonal to the traveling surface in a non-inclined state by subtracting the error value from the first distance value.

Further, the controller may calculate the first distance value by multiplying a cosine value (cos θ) of the inclination angle by the first measurement value.

Further, the controller may calculate the second distance value by multiplying a cosine value (cos θ) of the inclination angle by the second measurement value.

Further, the controller may instruct maintenance of a corresponding point when the step difference of the travel rail is equal to or greater than a predetermined threshold value.

Further, the controller may control the vehicle to operate at a reduced speed when passing a corresponding point when the step difference of the travel rail is equal to or greater than a predetermined threshold value.

Further, the controller may control the vehicle to bypass a corresponding point when the step difference of the travel rail is equal to or greater than a predetermined threshold value.

Another exemplary embodiment of the present invention provides a method of measuring a step difference of a travel rail on which an article transferring apparatus travels, the method including: a distance measurement operation in which each of a front displacement sensor and a rear displacement sensor disposed apart from each other by a predetermined interval along a traveling direction of the article transferring apparatus measures a distance value to a traveling surface of the travel rail; an inclination measurement operation of measuring an inclination angle of the article transferring apparatus; a correction operation of correcting an error between a first measurement value of the front displacement sensor and a second measurement value of the rear displacement sensor by using the inclination angle; and a determination operation of determining a step difference of the travel rail through a first distance value at which the front displacement sensor is orthogonal to the traveling surface and a second distance value at which the rear displacement sensor is orthogonal to the traveling surface calculated in the correction step.

Further, the first distance value may be a product of a cosine value (cos θ) of the inclination angle and the first measurement value.

Further, the determination operation may include calculating an error value by multiplying a sine value (sin θ) of the inclination angle by a distance value between the first displacement sensor and the second displacement sensor, and calculating an actual distance value at which the front displacement sensor is orthogonal to the traveling surface in a non-inclined state by subtracting the error value from the first distance value.

Further, the second distance value may be a product obtained by multiplying a cosine value (cos θ) of the inclination angle by the second measurement value.

Further, the determination operation may include, when the step difference of the travel rail is equal to or greater than a predetermined threshold value, instructing maintenance of a corresponding point.

Further, the determination operation may include, when the step difference of the travel rail is equal to or greater than a predetermined threshold value, controlling the article transferring apparatus to operate at a reduced speed or bypass a corresponding point.

Still another exemplary embodiment of the present invention provides a transferring system, including: a travel rail including a first rail and a second rail disposed along a travel path; and an article transferring apparatus travelling along the travel rail, in which the travel rail has a straight section and a curved section connected to the straight section, and the article transferring apparatus includes: a vehicle traveling along the travel rail; a hoist module connected to the vehicle and transferring an article; a step difference measurement unit which is installed in the vehicle, and measures a step difference of the travel rail by measuring distances values to a traveling surface of the travel rail by a first displacement sensor and a second displacement sensor arranged at a predetermined interval along a travel direction; and a controller for determining whether there is a step difference of the travel rail by correcting an error between a first measurement value of the first displacement sensor and a second measurement value of the second displacement sensor according to an inclination of the vehicle.

Further, the transferring system may further include an inclination sensor unit for detecting an inclination angle of the vehicle and providing the inclination angle value to the controller, in which the controller may correct an error between the first measurement value and the second measurement value by using the inclination angle, and calculates a first distance value at which the first displacement sensor is orthogonal to the traveling surface and a second distance value at which the second displacement sensor is orthogonal to the traveling surface.

Further, the controller may calculate the first distance value by multiplying a cosine value (cos θ) of the inclination angle by the first measurement value, and calculate an error value by multiplying a sine value (sin θ) of the inclination angle by a distance value between the first displacement sensor and the second displacement sensor, and calculate an actual distance value at which the front displacement sensor is orthogonal to the traveling surface in a non-inclined state by subtracting the error value from the first distance value.

Further, the controller may calculate the second distance value by multiplying a cosine value (cos θ) of the inclination angle by the second measurement value.

Further, the controller may determine whether or not there is a step difference of the travel rail only while the article transferring apparatus passes through a straight section of the travel rail, and when the step difference of the travel rail is equal to or greater than a predetermined threshold value, the article transferring apparatus may operate at a reduced speed or bypasses a corresponding point when passing the corresponding point.

According to the exemplary embodiment of the present invention, it is possible to detect whether or not there is a step difference of an actual travel rail by calculating an actual distance value rather than measurement values of displacement sensors.

According to the exemplary embodiment of the present invention, it is possible to minimize misdetection of displacement sensors.

The effect of the present invention is not limited to the foregoing effects, and those skilled in the art may clearly understand non-mentioned effects from the present specification and the accompanying drawings.

### BRIEF DESCRIPTION OF THE DRAWINGS

FIG. 1 is a top plan view of a transferring facility provided with an article transferring apparatus.

FIG. 2 is a side view of the article transferring apparatus illustrating a situation in which a transferring target article is received and handed over to a mounting place.

FIGS. 3 and 4 are diagrams illustrating the article transferring apparatus.

FIG. 5 is an enlarged view of a main part of a vehicle in which a step difference measurement unit is installed.

FIG. 6 is a diagram for explaining a method of calculating an actual distance value of the step difference measurement unit.

FIG. 7 is a flowchart for explaining a method for measuring a step difference of a travel rail in the article transferring apparatus.

### DETAILED DESCRIPTION

Hereinafter, an exemplary embodiment of the present invention will be described more fully hereinafter with reference to the accompanying drawings, in which exemplary embodiments of the invention are illustrated. However, the present invention can be variously implemented and is not limited to the following exemplary embodiments. In the following description of the present invention, a detailed description of known functions and configurations incorporated herein is omitted to avoid making the subject matter of the present invention unclear. In addition, the same reference numerals are used throughout the drawings for parts having similar functions and actions.

Unless explicitly described to the contrary, the word “comprise” and variations, such as “comprises” or “comprising” will be understood to imply the inclusion of stated elements but not the exclusion of any other elements. It will be appreciated that terms “including” and “having” are intended to designate the existence of characteristics, numbers, steps, operations, constituent elements, and components described in the specification or a combination thereof, and do not exclude a possibility of the existence or addition of one or more other characteristics, numbers, steps, operations, constituent elements, and components, or a combination thereof in advance.

Singular expressions used herein include plurals expressions unless they have definitely opposite meanings in the context. Accordingly, shapes, sizes, and the like of the elements in the drawing may be exaggerated for clearer description.

Terms, such as first and second, are used for describing various constituent elements, but the constituent elements are not limited by the terms. The terms are used only to discriminate one constituent element from another constituent element. For example, without departing from the scope of the invention, a first constituent element may be named as a second constituent element, and similarly a second constituent element may be named as a first constituent element.

It should be understood that when one constituent element referred to as being “coupled to” or “connected to” another constituent element, one constituent element can be directly coupled to or connected to the other constituent element, but intervening elements may also be present. In contrast, when one constituent element is “directly coupled to” or “directly connected to” another constituent element, it should be understood that there are no intervening element present. Other expressions describing the relationship between the constituent elements, such as “between ˜” and “just between ˜” or “adjacent to ˜” and “directly adjacent to ˜” should be interpreted similarly.

All terms used herein including technical or scientific terms have the same meanings as meanings which are generally understood by those skilled in the art unless they are differently defined. Terms defined in generally used dictionary shall be construed that they have meanings matching those in the context of a related art, and shall not be construed in ideal or excessively formal meanings unless they are clearly defined in the present application.

The foregoing detailed description illustrates the present invention. Further, the above content illustrates and describes the exemplary embodiment of the present invention, and the present invention can be used in various other combinations, modifications, and environments. That is, the foregoing content may be modified or corrected within the scope of the concept of the invention disclosed in the present specification, the scope equivalent to that of the disclosure, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

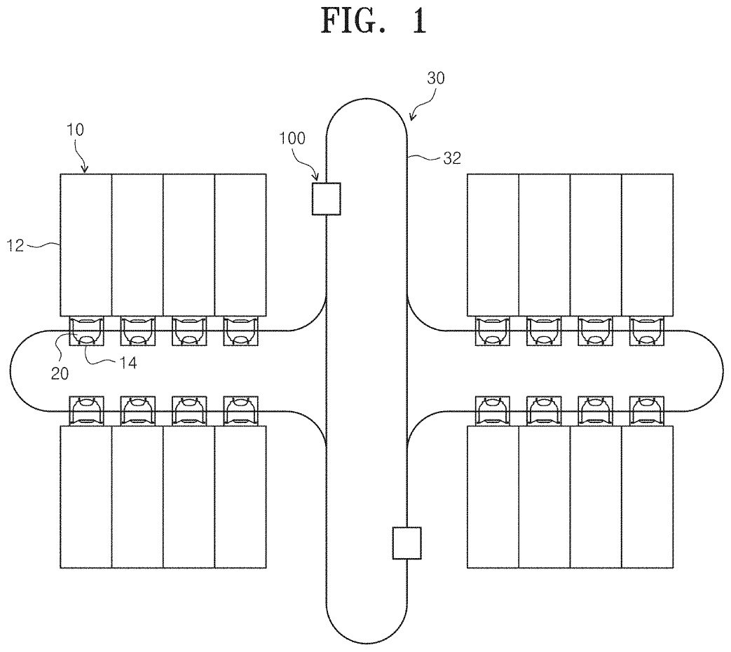

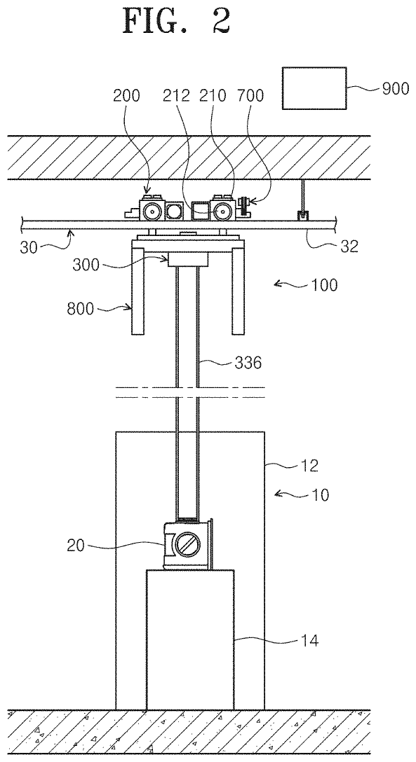

FIG. 1 is a top plan view of a transferring facility provided with an article transferring apparatus, and FIG. 2 is a side view of the article transferring apparatus illustrating a situation in which a transferring target article is received and handed over to a mounting place.

As illustrated in FIGS. 1 and 2, an article transferring apparatus 100 may include a transferring vehicle for transferring a transferring target article 20 to a transferring target place 10.

In the present exemplary embodiment, the article transferring apparatus 100 transfers the transferring target article 20 to each of the transferring target places 10 in a transferring facility having a plurality of transferring target places 10. The transferring target article 20 is a target for transferring, and may be, for example, a single article or may be a combination of a plurality of articles, such as a contained article and a container for containing the contained article. In the present exemplary embodiment, the transferring target article 20 may be a substrate accommodating container, such as a Front Opening Unified Pod (FOUP) in which a plurality of substrates is accommodated.

In the present exemplary embodiment, the transferring target place 10 includes a processing device 12 for processing semiconductor substrates and a mounting place 14 for mounting the substrate accommodating container that is the transferring target article 20. For example, the processing device 12 takes out a semiconductor substrate from the substrate accommodating container 20 mounted on the mounting place 14 and processes the semiconductor substrate. Further, the processing device 12 accommodates the processed semiconductor substrate in the substrate accommodating container 20 mounted on the mounting place 14.

As illustrated in FIG. 1, a plurality of transferring target places 10 is provided in the transferring facility. For example, a transferring path 30 is provided in the transferring facility so as to pass through the plurality of transferring target places 10.

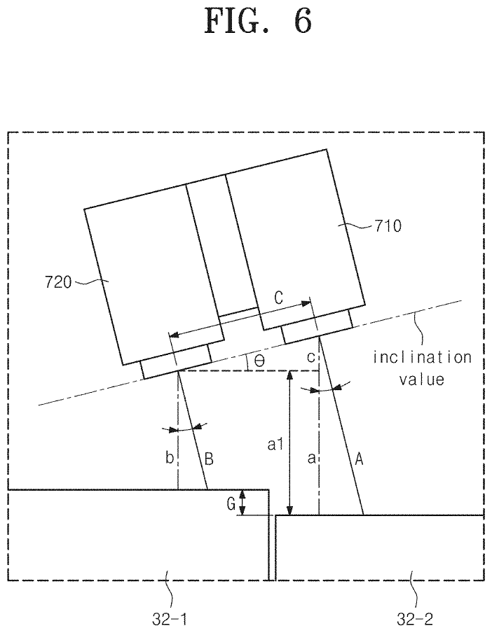

As illustrated in FIG. 2, in the present exemplary embodiment, the transferring path 30 is defined by a travel rail 32 connected to the ceiling. Further, the mounting place 14 may be installed below the travel rail 32 and at the same time overlapping the travel rail 32 in top plan view (see FIG. 1). Referring to FIG. 1, the travel rail 32 may include a straight section and a curved section. As illustrated in FIG. 6, in a traveling surface of the travel rail 32, for example, a step difference may be formed in a portion where a first rail 32-1 and a second rail 32-2 constituting the travel rail 32 are connected to each other.

the present exemplary embodiment, the article transferring apparatus 100 may be an Overhead Hoist Transport (OHT) device. The article transferring apparatus may travel on the travel rail 32 and transfer the plurality of transferring target articles 20 to the transferring target place 10. In the present exemplary embodiment, a plurality of the article transferring apparatuses 100 is provided in the transferring facility. Then, as illustrated in FIG. 2, the article transferring apparatus 100 may transfer three transferring target articles, and transfers the transferring target articles 20 to the mounting place 14. In other words, the article transferring apparatus 100 moves down the transferring target article 20 from the height at which the article transferring apparatus 100 is disposed (the height of the travel rail 32) toward the mounting place 14 provided below the height and mounts the transferring target article 20 on the mounting place 14.

Hereinafter, an example in which the article transferring apparatus 100 transfers a container in which a substrate, such as a wafer, is accommodated to semiconductor processing devices disposed in a semiconductor manufacturing line will be described as an example. However, the present invention is not limited thereto, and the article transferring apparatus of the present exemplary embodiment may be equally or similarly applied to various manufacturing lines requiring transferring of articles and/or containers in which articles are accommodated.

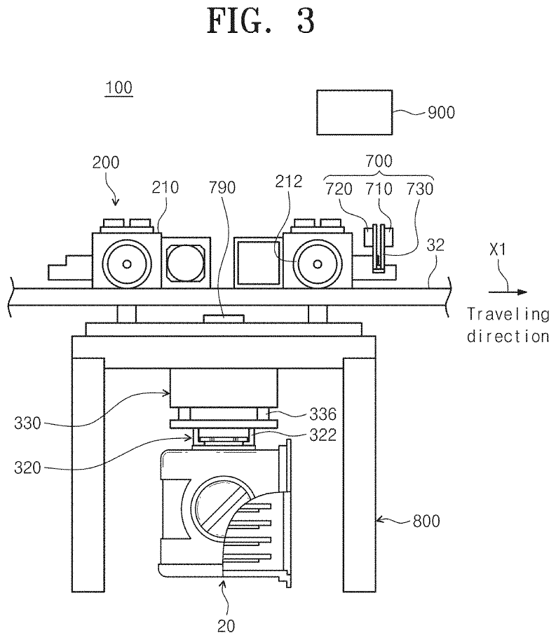

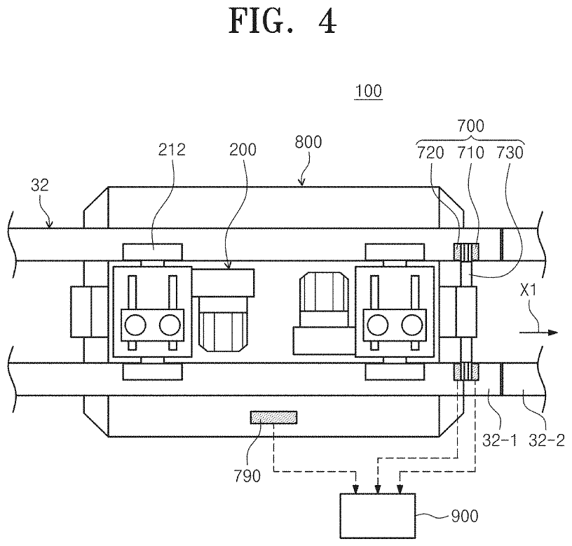

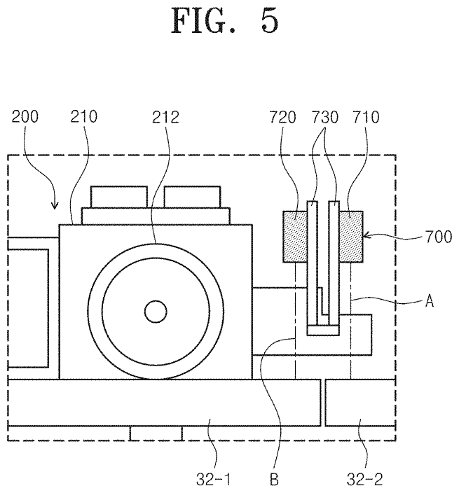

FIGS. 3 and 4 are drawings for explaining the article transferring apparatus, and FIG. 5 is an enlarged view of a main part for explaining a step difference measurement unit.

As illustrated in FIGS. 3 to 5, the article transferring apparatus 100 transfers a transferring target article 20 (hereinafter referred to as a substrate accommodating container). In the present exemplary embodiment, the article transferring apparatus transfers the substrate accommodating container in a suspended state.

In the present exemplary embodiment, the article transferring apparatus 100 may be a transferring vehicle including a vehicle 200, a vehicle main body 800, a step difference measurement unit 700, a hoist module 300, and a controller 900.

The vehicle 200 is a traveling module that travels along the travel rail 32 provided along the ceiling of a semiconductor manufacturing line by a separate driving unit. The vehicle 200 may include a body 210 having driving wheels 212 on both sides. An actuator (for example, a driving motor) for rotating the driving wheel 212 may be provided in the body 210. The body 210 travels along the travel rail 32. Specifically, the body 210 may travel while the travel wheels 212 rotate in a state of being in contact with the travel rail 32. Meanwhile, a steering wheel may be provided on the upper surface of the body 210. The steering wheel is provided to be movable along a horizontal direction perpendicular to the traveling direction of the body 210. For example, the steering wheel may move in the left and right directions of the body 210. The steering wheel may selectively contact a straight steering rail (not illustrated) for guiding straight traveling and a branch steering rail (not illustrated) for guiding branch traveling.

The vehicle main body 800 is connected to the vehicle 200 below the travel rail 32. The upper side of the vehicle main body 800 may be connected to the lower side of the vehicle 200 by at least one connection part. The vehicle main body 800 provides an interior space 802 in which the substrate accommodating container 20 is positioned. The vehicle main body 800 may be formed to have a structure in which both sides and a lower side are open so that the substrate accommodating container 20 may move in left and right directions and in a downward direction in the inner space 802. Here, both sides may be perpendicular to the traveling direction of the article transferring apparatus 100.

For example, when the hoist module 300 desires to transfer the substrate accommodating container 20 from the mounting place to the interior space 820 or transfers the substrate accommodating container 20 from the interior space 802 to the mounting place, the substrate accommodating container 20 is transferred through the open bottom surface 812 of the vehicle main body.

The hoist module 300 is provided on the vehicle main body 800. The hoist module 300 may load and unload substrate accommodating containers between the mounting place and the loading part. For example, the hoist module 300 may include a gripper unit 320 for picking up the substrate accommodating container 20 and a lifting unit 330 for lifting the gripper unit 320.

The gripper unit 320 grips or ungrips the substrate accommodating container 20. The gripper unit 320 may be connected to the lifting unit 330 through a plurality of lifting belts 336 and may include grippers 322 for gripping the substrate accommodating container 20. In addition, a flange configured to be gripped by the grippers 322 may be provided on an upper portion of the substrate accommodating container 20.

The gripper unit 320 may include a gripper driver (not illustrated) for driving the grippers 322. For example, the gripper driver may operate the grippers 322 using a cam plate and a cam follower, and may also include a motor, a ball screw, and the like to move the cam plate. However, since the configuration of the gripper unit 320 itself may be changed in various ways, the scope of the present invention will not be limited thereby. The gripper unit 320 may be moved vertically by the lifting unit 330.

The lifting unit 330 moves the gripper unit 320 in the vertical direction. The lifting unit 330 may include a driver and the lifting belt 336. The lifting belt of the lifting unit 330 may be connected to the gripper unit 320. The lifting belt 336 may move the gripper unit 320 in the vertical direction by driving force generated by the driver. For example, the driver may generate driving force to wind or unwind the lifting belt 336 to move the gripper unit 320 in the vertical direction. However, the present invention is not limited thereto, and the lifting unit may be modified with various known devices capable of lifting and lowering the gripper unit 320.

The step difference measurement unit 700 is installed on the vehicle 200. The step difference measurement unit 700 is located at the front in a travel direction X1 of the vehicle 200. The step difference measurement unit 700 may include a bracket 730, a front displacement sensor 710, and a rear displacement sensor 720. The front displacement sensor 710 and the rear displacement sensor 720 are installed on the bracket 730 so as to be separated by a predetermined distance. Each of the front displacement sensor 710 and the rear displacement sensor 720 may measure a distance value to the traveling surface of the travel rail 32. For example, the front displacement sensor 710 and the rear displacement sensor 720 may use either ultrasonic waves or electromagnetic waves.

Meanwhile, an inclination sensor unit 790 may be mounted on the vehicle 200. The inclination sensor unit 790 may measure a inclination angle of the vehicle 200 and provide the measured inclination angle to the controller 900. The inclination sensor unit 790 may also be installed on the vehicle body 800.

The measured values measured by the front displacement sensor 710 and the rear displacement sensor 720 and the inclination angle measured by the inclination sensor unit 790 may be provided to the controller 900.

The controller 900 corrects an error between a first measurement value of the front displacement sensor 710 and a second measurement value of the rear displacement sensor 720 according to the inclination of the vehicle 200 to determine whether the travel rail 32 has a step difference. The controller 900 may correct an error between the first measurement value and the second measurement value by using the inclination angle and calculate a first distance value at which the front displacement sensor 710 is orthogonal to the traveling surface and a second distance value at which the rear displacement sensor 720 is orthogonal to the traveling surface.

Here, it is preferable that the controller 900 determines whether there is a step difference only in the straight section of the travel rail 32. Also, the controller 900 may determine whether there is a step difference in an acceleration or deceleration section rather than a section in which the article transferring apparatus moves at a constant speed.

Hereinafter, a process of determining a step difference of a travel rail in the article transferring apparatus having the above configuration will be described.

FIG. 6 is a diagram for explaining a method of calculating an actual distance value of the step difference measurement unit.

Referring to FIGS. 4 and 6, the controller 900 multiplies a cosine value (cos θ) of an inclination angle by a second measurement value (B) to calculate a second distance value (b).

b=B*cos θ

The controller 900 calculates a first distance value (a) by multiplying the cosine value (cos θ) of the inclination angle by a first measurement value (A).

a=A*cos θ

The controller 900 multiplies a sine value (sin θ) of the inclination angle by a distance value between the front displacement sensor 710 and the rear displacement sensor 720 to calculate the error value (c).

c=C*sin θ

When the error value (c) is subtracted from the first distance value (a), the controller 900 may calculate an actual distance value (a1) in which the front displacement sensor 710 is orthogonal to the traveling surface in a normal traveling state (the vehicle is not inclined).

a1=a˜c

A step difference (G) of the travel rail 32 is a difference value between the actual distance value (a1) and the second distance value (b), and the controller 900 determines that the operation of the travel rail 32 has abnormality when the step difference (G) is equal to or greater than a predetermined threshold value.

G=a1 ˜b

The controller 900 requests maintenance of the corresponding point to a high-rank system when the step difference (G) of the travel rail 32 is equal to or greater than the predetermined threshold value. In addition, when the step difference (G) of the travel rail 32 is equal to or greater than the predetermined threshold value, the controller 900 may control the vehicle 200 to drive at reduced speed when passing the corresponding point or control the vehicle to bypass the corresponding point.

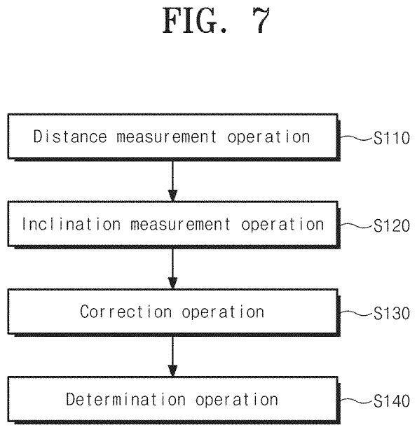

FIG. 7 is a flowchart for explaining a method for measuring a step difference of a travel rail in the article transferring apparatus.

Referring to FIG. 7, a method of measuring a step difference of a travel rail on which the article transferring apparatus travels may include a distance measurement operation S110, an inclination measurement operation S120, a correction operation S130, and a determination operation S140.

In the distance measurement operation S110, each of the front displacement sensor 710 and the rear displacement sensor 720 measures a distance value to the traveling surface of the travel rail 32.

In the tilt measurement operation S120, the inclination sensor unit 790 measures an inclination angle of the vehicle 200. The distance measurement operation S110 and the inclination measurement operation S120 may be performed simultaneously or the tilt measurement may be preceded.

In the correction operation S130, an errors between a first measurement value of the front displacement sensor 710 and a second measurement value of the rear displacement sensor 720 is corrected by using the inclination angle. The first distance value is a product of a cosine value (cos θ) of the inclination angle and the first measurement value, and the second distance value is a value obtained by multiplying a cosine value (cos θ) of the inclination angle by the second measurement value. Since the error correction process has been described in detail above, a description thereof will be omitted.

In the determination operation S140, a step difference of the travel rail 32 is determined through the first distance value at which the front displacement sensor 710 and the traveling surface are orthogonal to each other and the second distance value at which the rear displacement sensor 720 and the traveling surface are orthogonal to each other calculated in the correction operation S130. In the determination operation S140, when the step difference of the travel rail 32 is equal to or greater than a predetermined threshold value, maintenance of the corresponding point is requested to a high-rank system. Also, in the determination step, when the step difference of the travel rail is equal to or greater than the predetermined threshold value, the article transferring apparatus is controlled to drive at reduced speed or bypass the corresponding point when passing through the corresponding point.

In the foregoing exemplary embodiments, the method is described on the basis of a flow chart as a series of operations or blocks, but the present invention is not limited to the order of operations, and the operations of the present invention may occur in a different order or concurrently with other operations as described above. Further, those skilled in the art will understand that the operations illustrated in the flow chart are not exclusive, and that other operations may be included or one or more operations of the flow chart may be deleted without affecting the scope of the present invention.

The foregoing exemplary embodiments are presented for helping the understanding of the present invention, and do not limit the scope of the present invention, and it should be understood that various modified exemplary embodiments from the foregoing exemplary embodiments are also included in the scope of the present invention. The technical protection scope of the present invention should be determined by the technical spirit of the claims, and it should be understood that the technical protection scope of the present invention is not limited to the literal description of the claims itself, but is substantially equivalent to the technical value.

What is claimed is:

1. An article transferring apparatus, comprising:
a vehicle traveling along a travel rail installed on a ceiling;
a hoist module connected to the vehicle and transferring an article;
a step difference measurement unit which is installed in the vehicle, and measures a step difference of the travel rail by measuring distances values to a traveling surface of the travel rail by a first displacement sensor and a second displacement sensor arranged at a predetermined interval along a travel direction; and
a controller configured to determine whether there is a step difference of the travel rail by correcting an error between a first measurement value of the first displacement sensor and a second measurement value of the second displacement sensor according to an inclination of the vehicle.

2. The article transferring apparatus of claim 1, further comprising:
an inclination sensor unit for detecting an inclination angle of the vehicle and providing the inclination angle value to the controller.

3. The article transferring apparatus of claim 2, wherein the controller configured to correct an error between the first measurement value and the second measurement value by using the inclination angle, and calculate a first distance value at which the first displacement sensor is orthogonal to the traveling surface and a second distance value at which the second displacement sensor is orthogonal to the traveling surface.

4. The article transferring apparatus of claim 3, wherein the controller configured to calculate an error value by multiplying a sine value (sin θ) of the inclination angle by a distance value between the first displacement sensor and the second displacement sensor, and calculate an actual distance value at which the front displacement sensor is orthogonal to the traveling surface in a non-inclined state by subtracting the error value from the first distance value.

5. The article transferring apparatus of claim 3, wherein the controller configured to calculate the first distance value by multiplying a cosine value (cos θ) of the inclination angle by the first measurement value.

6. The article transferring apparatus of claim 3, wherein the controller configured to calculate the second distance value by multiplying a cosine value (cos θ) of the inclination angle by the second measurement value.

7. The article transferring apparatus of claim 1, wherein the controller configured to instruct maintenance of a corresponding point when the step difference of the travel rail is equal to or greater than a predetermined threshold value.

8. The article transferring apparatus of claim 1, wherein the controller configured to control the vehicle to operate at a reduced speed when passing a corresponding point when the step difference of the travel rail is equal to or greater than a predetermined threshold value.

9. The article transferring apparatus of claim 1, wherein the controller configured to control the vehicle to bypass a corresponding point when the step difference of the travel rail is equal to or greater than a predetermined threshold value.

10.-15. (canceled)

16. A transferring system, comprising:
a travel rail including a first rail and a second rail disposed along a travel path; and
an article transferring apparatus travelling along the travel rail,
wherein the travel rail has a straight section and a curved section connected to the straight section, and
the article transferring apparatus includes:
a vehicle traveling along the travel rail;
a hoist module connected to the vehicle and transferring an article;
a step difference measurement unit which is installed in the vehicle, and measures a step difference of the travel rail by measuring distances values to a traveling surface of the travel rail by a first displacement sensor and a second displacement sensor arranged at a predetermined interval along a travel direction; and
a controller configured to determine whether there is a step difference of the travel rail by correcting an error between a first measurement value of the first displacement sensor and a second measurement value of the second displacement sensor according to an inclination of the vehicle.

17. The transferring system of claim 16, further comprising:
an inclination sensor unit for detecting an inclination angle of the vehicle and providing the inclination angle value to the controller,
wherein the controller configured to correct an error between the first measurement value and the second measurement value by using the inclination angle, and calculate a first distance value at which the first displacement sensor is orthogonal to the traveling surface and a second distance value at which the second displacement sensor is orthogonal to the traveling surface.

18. The transferring system of claim 17, wherein the controller configured to calculate the first distance value by multiplying a cosine value (cos θ) of the inclination angle by the first measurement value,
calculate an error value by multiplying a sine value (sin θ) of the inclination angle by a distance value between the first displacement sensor and the second displacement sensor, and
calculate an actual distance value at which the front displacement sensor is orthogonal to the traveling surface in a non-inclined state by subtracting the error value from the first distance value.

19. The transferring system of claim 17, wherein the controller configured to calculate the second distance value by multiplying a cosine value (cos θ) of the inclination angle by the second measurement value.

20. The transferring system of claim 16, wherein the controller configured to determine whether or not there is a step difference of the travel rail only while the article transferring apparatus passes through a straight section of the travel rail, and
when the step difference of the travel rail is equal to or greater than a predetermined threshold value, the article transferring apparatus operates at a reduced speed or bypasses a corresponding point when passing the corresponding point.
